(19) United States
(12) Patent Application Publication
(10) Pub. No.: US 2015/0264813 A1
(43) Pub. Date: Sep. 17, 2015

(54) CHIP-STACK INTERPOSER STRUCTURE INCLUDING PASSIVE DEVICE AND METHOD FOR FABRICATING THE SAME

(71) Applicant: United Microelectronics Corp., Hsinchu (TW)

(72) Inventors: Zhi-Biao Zhou, SINGAPORE (SG); Shao-Hui Wu, Singapore (SG); Chi-Fa Ku, Kaohsiung City (TW)

(73) Assignee: United Microelectronics Corp., Hsinchu (TW)

(21) Appl. No.: 14/204,898

(22) Filed: Mar. 11, 2014

(51) Int. Cl. H05K 1/18; H05K 3/46; H05K 1/02; H05K 1/16; H05K 1/11

(52) U.S. Cl. CPC H05K 1/183; H05K 1/162; H05K 1/115; H05K 1/0298; H05K 3/46; H05K 2201/09036

(57) ABSTRACT

A chip-stack interposer structure including a passive device is described, including an interposing layer, a capacitor, a first contact and a second contact. The capacitor is embedded in or disposed on the interposing layer, including a first electrode, a second electrode and a dielectric layer between the first and the second electrodes. The first contact is connected with the first electrode. The second contact is connected with the second electrode. The first electrode and the second electrode are disposed at the same side of the interposing layer or at different sides of the interposing layer.

### BACKGROUND OF THE INVENTION

1. Field of Invention

This invention relates to an integrated circuit structure and its fabrication, and particularly relates to a chip-stack interposer structure including a passive device, and a method for fabricating the same structure.

2. Description of Related Art

In order to improve the integration degree and the performance of an integrated circuit, it is possible to stack multiple chips and utilize an interposer structure including through-silicon vias (TSV) and a redistribution layer (RDL) for electrical connection between the chips.

However, the conventional TSV/RDL process does not include fabrication steps of passive devices such as capacitors, resistors and inductors. Hence, when passive devices are required, it is necessary to connect separately fabricated passive devices so that the manufacturing process is more complicated.

Moreover, the conventional RDL process usually includes a 4×/6× BEOL (back end of line) metal process, which includes trench/via etching, Cu-seed deposition, Cu ECP (electrochemical plating) and Cu CMP and therefore usually has a high cost.

### SUMMARY OF THE INVENTION

Accordingly, this invention provides a chip-stack interposer structure including a passive device, which is capable of avoiding inconvenience of connecting a separately fabricated passive device.

This invention also provides a method for fabricating a chip-stack interposer structure including a passive device, which not only can avoid the inconvenience of connecting a separately fabricated passive device, but also can reduce the cost of the RDL process in some embodiments.

The chip-stack interposer structure including a passive device according to an aspect of this invention includes an interposing layer, a capacitor, a first contact and a second contact. The capacitor is embedded in or disposed on the interposing layer, and includes a first electrode, a second electrode, and a dielectric layer between the first and the second electrodes, wherein a portion of the first electrode does not overlap with the second electrode, and a portion of the second electrode does not overlap with the first electrode. The first contact is connected with the first electrode. The second contact is connected with the second electrode. The first and the second contacts are disposed at the same side of the interposing layer. Examples of such interposer structure can be seen in the first to fourth embodiments of this invention described later.

In an embodiment of the above aspect of this invention, the interposer structure further includes an insulating layer at a first side of the interposing layer, wherein the first contact and the second contact are disposed in the insulating layer, penetrate the first electrode and the second electrode, respectively, and extend into the interposing layer. Examples of such interposer structure can be seen in the first embodiment of this invention described later.

In another embodiment of the above aspect of this invention, the interposer structure further includes a first insulating layer at a first side of the interposing layer, wherein the first contact and the second contact are disposed in the first insulating layer and do not penetrate the first electrode and the second electrode. Examples of such interposer structure can be seen in the first and second embodiments of this invention described later. The chip-stack interposer structure may further include a through-substrate via in the interposing layer, and a metal wiring disposed in the first insulating layer and crossing over the through-substrate via. Examples of such interposer structure can be seen in the fourth embodiment of this invention described later. In such case, the chip-stack interposer structure may further include a second insulating layer between the surface of the first side of the interposing layer and the first insulating layer, wherein at least a portion of each of the first electrode and the second electrode is between the first insulating layer and the second insulating layer, and the metal wiring extends into the second insulating layer. Examples of such interposer structure can be seen in the third embodiment of this invention described later. In addition, the dimension of the metal wiring may be substantially the same as the dimension of the through-substrate via, or be different from the dimension of the through-substrate via (Examples of such interposer structure can be seen in the third and fourth embodiments of this invention described later).

The chip-stack interposer structure including a passive device according to another aspect of this invention includes an interposing layer, a capacitor, a first contact and a second contact. The capacitor is embedded in or disposed on the interposing layer, and includes a first electrode, a second electrode, and a dielectric layer between the first electrode and the second electrode. The first contact is connected with the first electrode. The second contact is connected with the second electrode. The first contact and the second contact are disposed at different sides of the interposing layer. Examples of such interposer structure can be seen in the fifth and sixth embodiments of this invention described later.

In an embodiment of the another aspect of this invention, the interposer structure further includes an insulating layer at a first side of the interposing layer, wherein the first contact is disposed in the insulating layer, and the second contact is disposed in the interposing layer and extends toward a second side of the interposing layer.

The method for fabricating a chip-stack interposer structure including a passive device of this invention includes the following steps. An interposing layer is provided. A capacitor is formed, which is embedded in or disposed on the interposing layer and includes a first electrode, a second electrode, and a dielectric layer between the first and the second electrodes. A first contact is formed, which is connected with the first electrode. A second contact is formed, which is connected with the second electrode.

In an embodiment of the above method of this invention, forming the capacitor includes sequentially fondling the first electrode, the dielectric layer and the second electrode, wherein a portion of the first electrode does not overlap with the second electrode, a portion of the second electrode does not overlap with the first electrode, and the first and the second contacts are disposed at the same side of the interposing layer. Examples of such method can be seen in the 1^{st} to 4^{th} embodiments of this invention.

The above embodiment may further include the following steps. An insulating layer is formed at a first side of the interposing layer. A through-substrate via is formed in the insulating layer and the interposing layer, and simultaneously the first contact and the second contact are formed in the insulating layer, through the first electrode and the second electrode, respectively, and into the interposing layer. Examples of such method can be seen in the first embodiment of this invention.

Alternatively, the above embodiment may further include the following steps. An insulating layer is formed at a first side of the interposing layer. A through-substrate via is formed in the insulating layer and the interposing layer. The first contact and the second contact are formed in the insulating layer but do not penetrate the first electrode and the second electrode. Examples of such method can be seen in the second and third embodiments of this invention described later.

Alternatively, the above embodiment may further include the following steps. A through-substrate via is &limed in the interposing layer. A first insulating layer is formed at a first side of the interposing layer. A metal wiring crossing over the through-substrate via is formed in the first insulating layer, while the first contact and the second contact are formed. Examples of such method can be seen in the fourth embodiment of this invention described later. In such case, the method may further include forming a second insulating layer on the surface of the first side of the interposing layer after the through-substrate via is formed but before the capacitor is formed, wherein at least a portion of each of the first electrode and the second electrode is between the first insulating layer and the second insulating layer, and the metal wiring extends into the second insulating layer.

In another embodiment of the above method of this invention, the first and the second contacts are disposed at different sides of the interposing layer. Examples of such method can be seen in the fifth and sixth embodiments of this invention.

The another embodiment may further include forming an insulating layer at a first side of the interposing layer, wherein the first contact is formed in the insulating layer, and the second contact is formed in the interposing layer and extends toward a second side of the interposing layer. Examples of such method can be seen in the fifth embodiment of this invention described later. In such case, the another embodiment may further include the following steps. A through-substrate via is formed in the interposing layer while the second contact is formed. A metal wiring crossing over the through-substrate via is formed in the insulating layer while the first contact is formed.

Alternatively, the another embodiment may further include the following steps. A through-substrate via is formed in the interposing layer before the first electrode is formed. A metal wiring is formed crossing over the through-substrate via. A first insulating layer is formed over the metal wiring. A second insulating layer is formed after the second electrode is formed. The second contact is formed in the second insulating layer. Examples of such method can be seen in the sixth embodiment of this invention described later. In such case, the another embodiment may further include the following steps. A conductive layer is formed over the interposing layer before the metal wiring is formed. A patterned photoresist layer is formed on the conductive layer, having therein a trench exposing a portion of the conductive layer and crossing over the through-substrate via, wherein the metal wiring is formed in the trench later. The patterned photoresist layer is removed after the metal wiring is formed.

Because the interposer structure or its fabrication method of this invention integrates a passive device such as a capacitor or its fabrication, inconvenience of connecting a separately fabricated passive device as seen in the prior art can be avoided

Moreover, when the above method that forms a conductive layer, a patterned photoresist layer and a metal wiring in openings in the photoresist layer is used to form a redistribution layer (RDL), no etching or CMP process is needed, so the cost of the RDL process can be remarkably lowered.

In order to make the aforementioned and other objects, features and advantages of the present invention comprehensible, a preferred embodiment accompanied with figures is described in detail below.

### BRIEF DESCRIPTION OF THE DRAWINGS

FIGS. 1A-1E schematically illustrate, in a cross-sectional view, a method for fabricating a chip-stack interposer structure including a passive device according to a first embodiment of this invention, wherein FIG. 1 E also illustrates the resulting interposer structure.

FIGS. 2A and 2B schematically illustrate, in a cross-sectional view, a method for fabricating a chip-stack interposer structure including a passive device according to a second embodiment of this invention, wherein FIG. 2B also illustrates the resulting interposer structure.

FIGS. 3A-3C schematically illustrate, in a cross-sectional view, a method for fabricating a chip-stack interposer structure including a passive device according to a third embodiment of this invention, wherein FIG. 3C also illustrates the resulting interposer structure.

FIG. 4 schematically illustrates, in a cross-sectional view, a method for fabricating a chip-stack interposer structure including a passive device according to a fourth embodiment of this invention, and also the resulting interposer structure.

FIGS. 5A and 5B schematically illustrate, in a cross-sectional view, a method for fabricating a chip-stack interposer structure including a passive device according to a fifth embodiment of this invention, wherein FIG. 5B also illustrates the resulting interposer structure.

FIGS. 6A-6G schematically illustrate, in a cross-sectional view, a method for fabricating a chip-stack interposer structure including a passive device according to a sixth embodiment of this invention, wherein FIG. 6G also illustrates the resulting interposer structure.

FIG. 7 schematically illustrates, in a top view, a chip-stack interposer structure integrated with various kinds of passive devices according to an embodiment of this invention.

### DESCRIPTION OF EMBODIMENTS

This invention will be further explained with the following embodiments and the accompanying drawings, which are not intended to restrict the scope of this invention. Among the following embodiments, the first to fourth ones relate to the former aspect of this invention in which a portion of the first electrode does not overlap with the second electrode, a portion of the second electrode does not overlap with the first electrode, and the first contact and the second contact are disposed at the same side of the interposing layer, and the fifth and sixth ones relate to the latter aspect of this invention in which the first and the second contacts are disposed at different sides of the interposing layer.

From the viewpoint of the method for fabricating the chip-stack interposer structure, the capacitor may be fabricated before the through-substrate via is formed, as in the first and second embodiments, or after the through-substrate via is formed, as in the third to sixth embodiments. The first and the second contacts of the capacitor may be formed simultaneously with the through-substrate via as in the first embodiment, or be formed after the through-substrate via is formed, as in the second to fourth embodiments, or be formed simultaneously with the through-substrate via and after the through-substrate via is formed, respectively, as in the fifth and sixth embodiments.

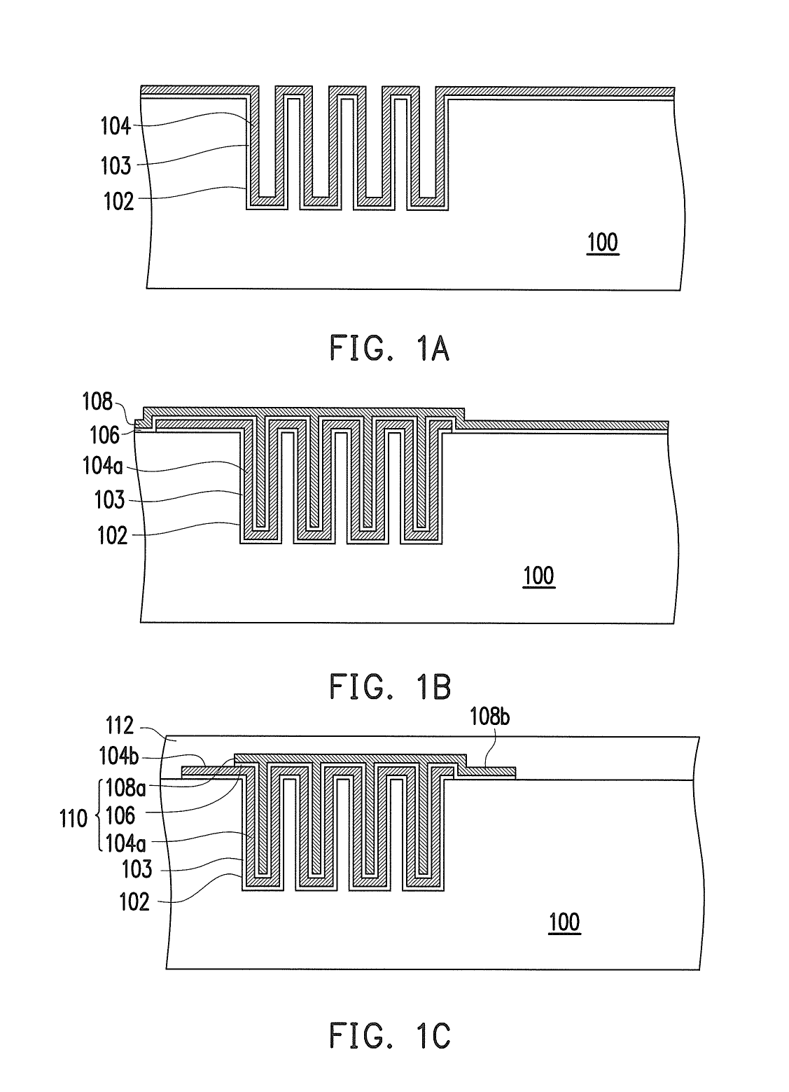

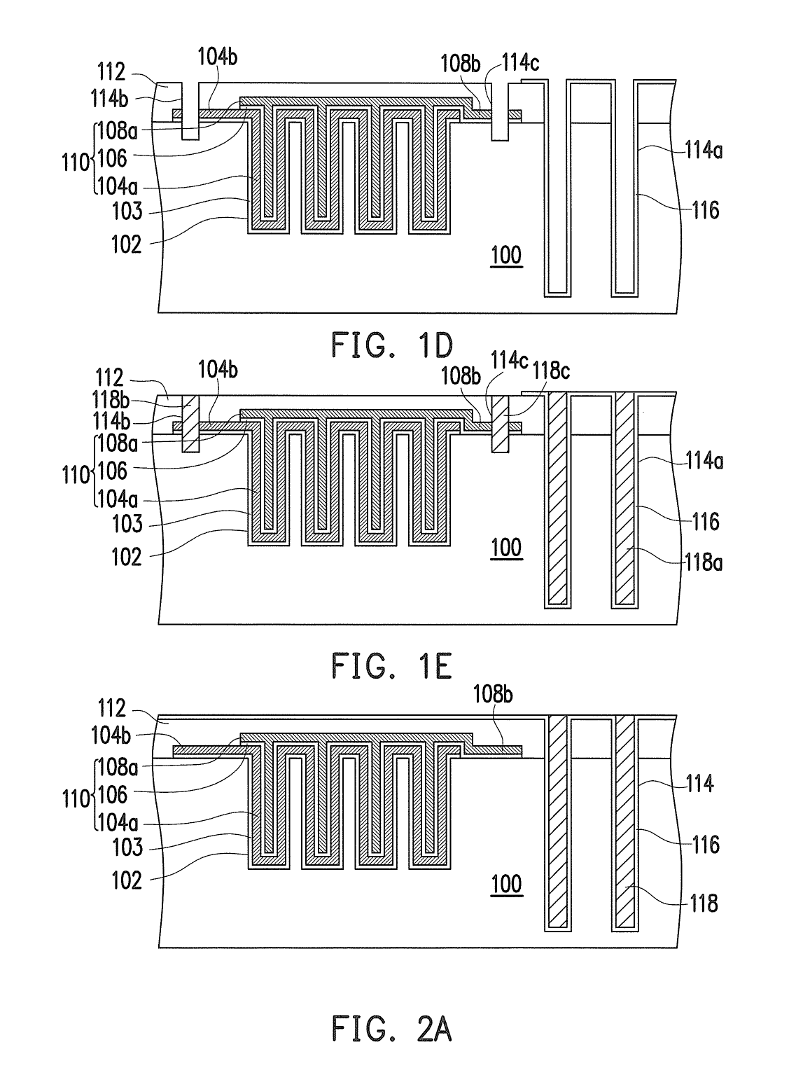

FIGS. 1A-1E schematically illustrate, in a cross-sectional view, a method for fabricating a chip-stack interposer structure including a passive device according to a first embodiment of this invention. FIG. 1E also illustrates the resulting structure.

Referring to FIG. 1A, an interposing layer 100 is provided, which may include Si or glass. Trenches 102 are formed in the interposing layer 100. A liner layer 103 and a conductive layer 104 are sequentially formed on the interposing layer 100 and in the trenches 102. The liner layer 103 may include silicon oxide. The conductive layer 104 may include doped poly-Si or metal, wherein the metal may be TiN, Ti, Ta, TaN or Al. Moreover, when the interposing layer 100 includes an insulating material like glass, the liner layer 103 may be omitted.

Referring to FIG. 1B, the conductive layer 104 is then patterned into a bottom electrode 104a, and then a dielectric layer 106 and another conductive layer 108 are sequentially formed on the interposing layer 100 and in the trenches 102, wherein the conductive layer 108 may fill up the trenches 102. The dielectric layer 106 may include an ONO composite layer, silicon oxide, SiN, aluminum oxide, HfO₂, ZrOₓ or a mixed/laminated material. Examples of the material of the conductive layer 108 are the same as the above examples of the material of the conductive layer 104.

Referring to FIG. 1C, the conductive layer 108 is patterned into a top electrode 108a, thus obtaining a capacitor 110. The patterns for patterning the conductive layer 104 and the conductive layer 108 are designed in a manner such that a portion 104b of the bottom electrode 104a over the surface of the interposer layer 100 does not overlap with the top electrode 108a and a portion 108b of the top electrode 108a over the surface of the interposer layer 100 does not overlap with bottom electrode 104a. An insulating layer 112 is then formed covering the interposer layer 100 and the capacitor 110, possibly include silicon oxide, SiN, silicon oxynitride (SiON) or low-temperature oxide (LTO).

Referring to FIG. 1D, through-substrate via holes 114a for containing through-substrate vias later are formed in the interposing layer 110 through the insulating layer 112, and simultaneously contact holes 114b and 114c are formed through the insulating layer 112, through the portion 104b of the bottom electrode 104a not overlapping with the top electrode 108a and the portion 108b of the top electrode 108a not overlapping with the bottom electrode 104a, respectively, and then into the interposing layer 100. Then, a liner layer 116 is formed on the sidewalls of the through-substrate via holes 114a, possibly by depositing a blanket layer of a liner material over the above resulting structure and them remove the liner material in the area of the contact holes 114b and 114c. The liner layer 116 may include silicon oxide. Moreover, when the interposing layer 100 includes an insulating material like glass, the liner layer 116 may be omitted.

Referring to FIG. 1E, thereafter, through-substrate vias 118a are formed in the through-substrate via holes 114a, and simultaneously contacts plugs 118b and 118c are formed in the contact holes 114b and 114c, respectively. The contacts plugs 118b and 118c penetrate the portion 104b of the bottom electrode 104a not overlapping with the top electrode 108a and the portion 108b of the top electrode 108a not overlapping with the bottom electrode 104a, respectively, and extend into the interposing layer 100. The process for forming the through-substrate vias 118a and the contacts plugs 118b and 118c may include deposition of a barrier layer and/or a seed layer, electrochemical plating (ECP) and chemical mechanical polishing (CMP), etc. The material of the through-substrate vias 118a and the contacts plugs 118b and 118c may be Cu. In addition, when the interposing layer 100 includes silicon, the through-substrate vias 118a are through-silicon vias (TSV). The same rule applies to the through-substrate vias in the second to sixth embodiments described later and also to other non-illustrated embodiments of this invention.

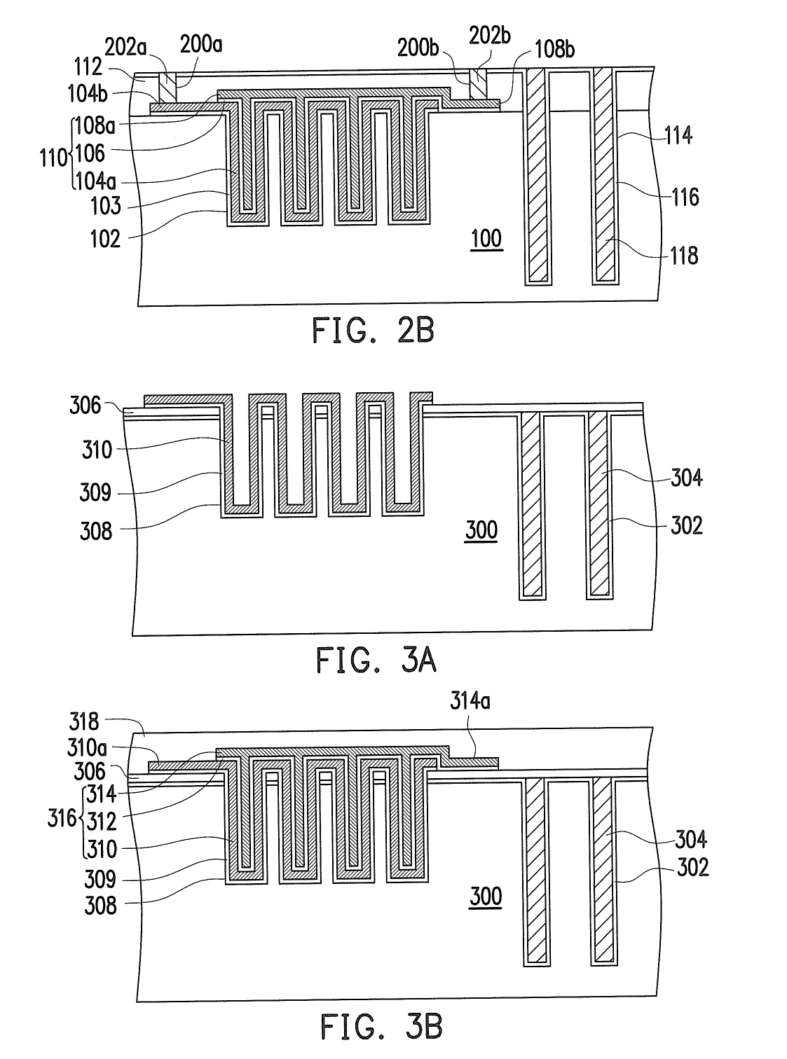

FIGS. 2A and 2B schematically illustrate, in a cross-sectional view, a method for fabricating a chip-stack interposer structure including a passive device according to a second embodiment of this invention. FIG. 2B also illustrates the resulting structure.

Referring to FIG. 2A, the capacitor 110 is formed, followed by coverage of the insulating layer 112, possibly by the method mentioned in the descriptions of the first embodiment illustrated in FIGS. 1A-1C. Through-substrate via holes 114 are then formed in the interposing layer 100 through the insulating layer 112. A liner layer 116 is then formed on the insulating layer 112 and on the sidewalls of the through-substrate via holes 114, and then through-substrate via 118 are formed in the through-substrate via holes 114, possibly by the method described above.

Referring to FIG. 2B, contact holes 200a and 200b are formed in the insulating layer 112, exposing the portion 104b of the bottom electrode 104a not overlapping with the top electrode 108a and the portion 108b of the top electrode 108a not overlapping with the bottom electrode 104a, respectively. Contact plugs 202a and 202b are then foamed in the contact holes 200a and 200b, contacting with the portion 104b of the bottom electrode 104a not overlapping with the top electrode 108a and the portion 108b of the top electrode 108a not overlapping with the bottom electrode 104a, respectively.

FIGS. 3A-3C schematically illustrate, in a cross-sectional view, a method for fabricating a chip-stack interposer structure including a passive device according to a third embodiment of this invention. FIG. 3C also illustrates the resulting structure.

Referring to FIG. 3A, through-substrate vias 304 are formed in the interposing layer 300, with a liner layer 302 therebetween, and then an insulating layer 306 is formed over the interposing layer 300 and the through-substrate vias 304. Trenches 308 are then formed in the insulating layer 306 and the interposing layer 300, and a liner layer 309 is fondled on the insulating layer 306 and in the trenches 308. A bottom electrode 310 is then formed on a part of the surface of the insulating layer 306 and in the trenches 308, possibly using the method mentioned in the descriptions in the first embodiment illustrated in FIGS. 1A and 1B.

Referring to FIG. 3B, a dielectric layer 312 and a top electrode 314 are sequentially formed on the insulating layer 306 and in the trenches 308, thus obtaining a capacitor 316. The patterns for defining the bottom electrode 310 and the top electrode 314 are designed in a manner such that a portion 310a of the bottom electrode 310 over the surface of the interposer layer 300 does not overlap with the top electrode 314 and a portion 314a of the top electrode 314 over the surface of the interposer layer 300 does not overlap with bottom electrode 310. Another insulating layer 318 is then formed covering the insulating layer 306 and the capacitor 316.

Referring to FIG. 3C, a trench 320a is formed in the insulating layers 318 and 316, and simultaneously contact holes 320b and 320c are formed in the insulating layer 318, exposing the portion 310a of the bottom electrode 310 not overlapping with the top electrode 314 and the portion 314a of the top electrode 314 not overlapping with bottom electrode 310, respectively. A metal wiring 322a is then formed in the trench 320a as a redistribution layer, and simultaneously contact plugs 322b and 322c are formed in the contact holes 320b and 320c, contacting with the portion 310a of the bottom electrode 310 not overlapping with the top electrode 314 and the portion 314a of the top electrode 314 not overlapping with bottom electrode 310, respectively. The dimension W₁ of the metal wiring 322a may be greater than the dimension W₂ of each through-substrate via 304, as shown in the figure. Alternatively, the dimension of the metal wiring 322a is smaller than or substantially the same as the dimension of each through-substrate via 304 (not shown).

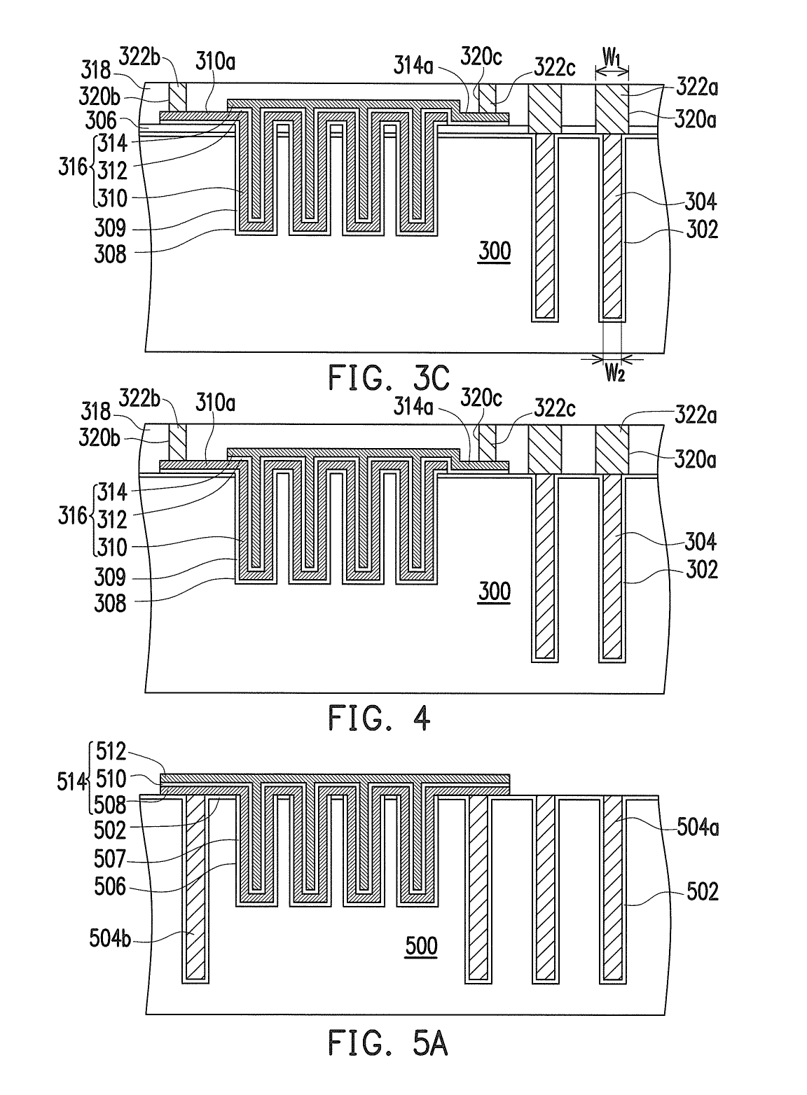

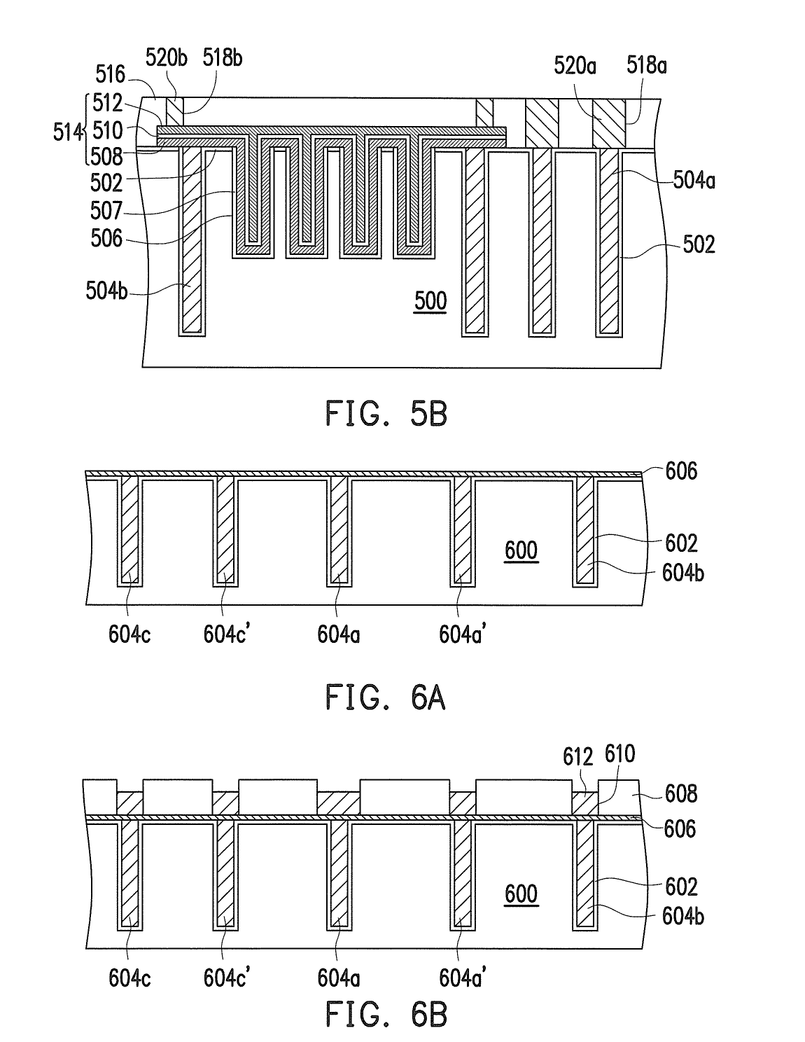

FIG. 4 schematically illustrates, in a cross-sectional view, a method for fabricating a chip-stack interposer structure including a passive device according to a fourth embodiment of this invention, and also the resulting interposer structure.

Referring to FIG. 4, the fourth embodiment differs from the third one above in that an insulating layer 306 is not formed after the through-substrate vias 304 are formed, and the trenches 308 are formed in the interposing layer 300 directly, followed by the fabrication process of the capacitor 316. Therefore, the metal wiring 322a is formed only in the insulating layer 318. The thickness of the insulating layer 318 may be increased as required to allow the metal wiring 322a has a required thickness.

FIGS. 5A and 5B schematically illustrate, in a cross-sectional view, a method for fabricating a chip-stack interposer structure including a passive device according to a fifth embodiment of this invention. FIG. 5B also illustrates the resulting structure.

Referring to FIG. 5A, through-substrate vias 504a and contact plugs 504b are formed in the interposing layer 500, with a liner layer 502 therebetween, wherein the contact plugs 504b have the same structure of the through-substrate vias 504a. Trenches 506 are then formed in the interposing layer 500, and then a liner 507 is formed in the trenches 506. A bottom electrode 508, a dielectric layer 510 and a top electrode 512 are then formed over the interposing layer 500 and in the trenches 506, thus obtaining a capacitor 514, wherein the bottom electrode 508 contacts with the contact plugs 504b. The top electrode 512, the dielectric layer 510 and the bottom electrode 508 may be defined by the same patterned mask layer to have aligned borders.

Referring to FIG. 5B, an insulating layer 516 is then formed covering the interposing layer 500 and the capacitor 514. Thereafter, in the insulating layer 516, a trench 518a is foil led exposing the through-substrate vias 504a, and simultaneously contact holes 518b are formed exposing portions of the top electrode 512. A metal wiring 520a is then formed in the trench 518a as a redistribution layer, and simultaneously contact plugs 520b are formed in the contact holes 518b and contact with the top electrode 512.

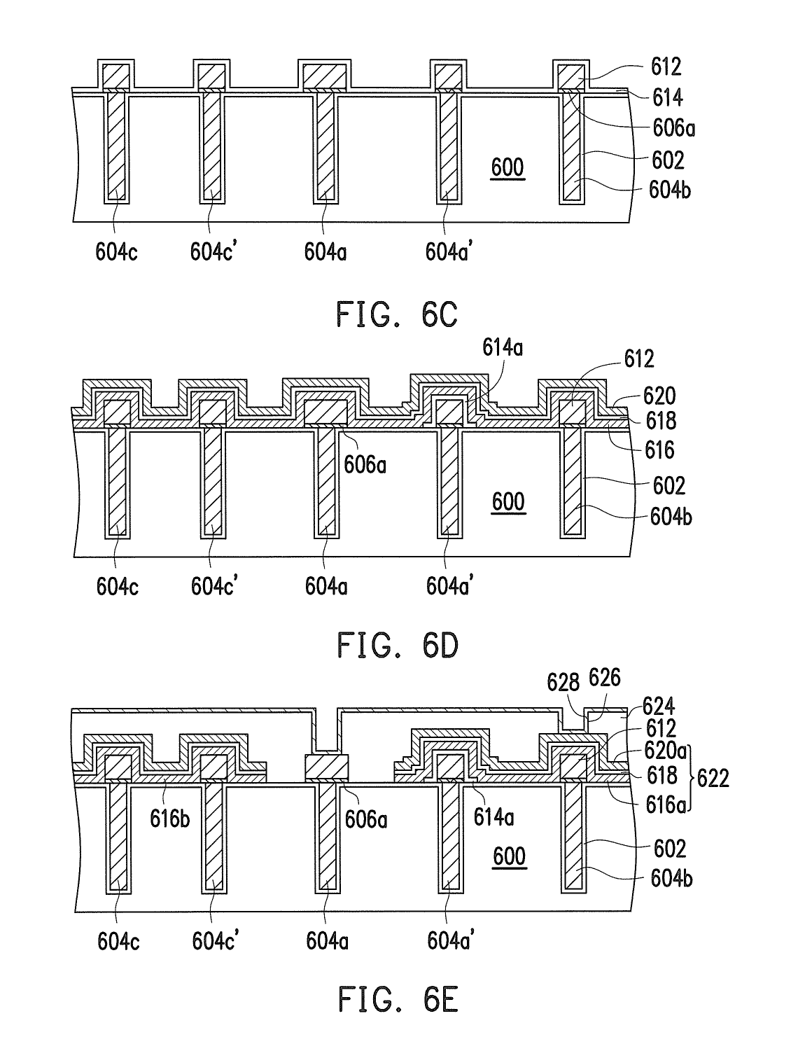

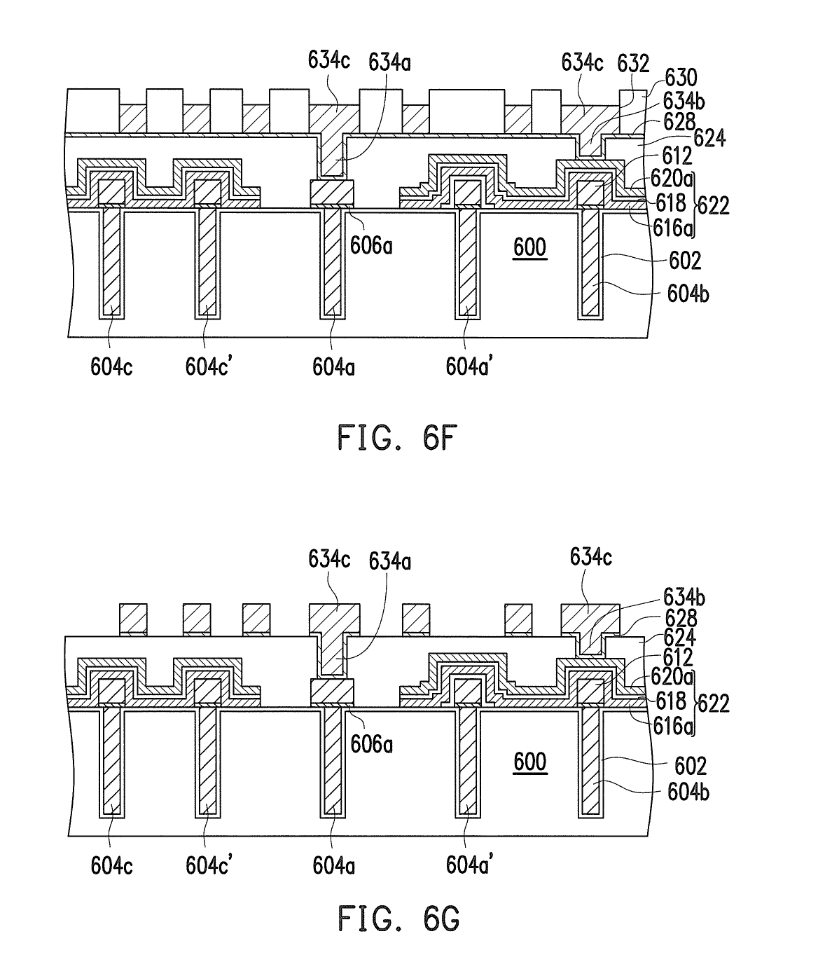

FIGS. 6A-6G schematically illustrate, in a cross-sectional view, a method for fabricating a chip-stack interposer structure including a passive device according to a sixth embodiment of this invention. FIG. 6G also illustrates the resulting structure.

Referring to FIG. 6A, through-substrate vias 604a and 604a′, a contact plug 604b of the bottom electrode of a capacitor, and contact plugs 604c and 604c′ of a resistor are formed in the interposing layer 600, with a liner layer 602 therebetween, wherein the contact plugs 604b, 604c and 604c′ have the same structure of the through-substrate vias 604a and 604a′. A conductive layer 606 is formed on the above resulting structure, possibly including a barrier layer and/or a seed layer. The barrier layer may include TiN, Ti, Ta or Ta, etc. The seed layer may include Cu.

Referring to FIG. 6B, a patterned photoresist layer 608 is then formed on the conductive layer 606, having therein a plurality openings 610 exposing portions of the conductive layer 606 over the through-substrate vias 604a and 604a′ and the contact plugs 604b, 604c and 604c′. A metal layer 612 is then filled in the openings 610 to serve as the first metal layer (M1) and respective extensions of the contact plugs 604b, 604c and 604c′, possibly through electrochemical plating (ECP).

Referring to FIG. 6C, the patterned photoresist layer 608 is removed, and the portions of the conductive layer 606 not covered by the metal layer 612 are removed. Thereafter, an insulating layer 614 is formed over the interposing layer 600 and on the surface of the metal layer 612, possibly including silicon oxide, SiN, SiON or LTO.

Referring to FIG. 6D, the insulating layer 614 is patterned to leave an isolation layer 614a on the portion of the metal layer 612 located over the through-substrate via 604a′ and requiring electrical isolation. Thereafter, a conductive layer 616, a dielectric layer 618 and another conductive layer 620 are sequentially formed on the resulting structure. The conductive layers 616 and 620 may include TiN, Ti, Ta, TaN, Al or doped poly-Si. The dielectric layer 618 may include an ONO composite layer, silicon oxide, SiN, aluminum oxide, HfO₂, ZrOₓ, or a mixed/laminated material.

Referring to FIG. 6E, the conductive layer 620, the dielectric layer 618 and the conductive layer 616 are patterned to form a capacitor 622 including a bottom electrode 616a, the dielectric layer 618 and a top electrode 620a, and a resistor 616a. The contact plug 604b is electrically connected with the bottom electrode 616a via the portions of the conductive layer 606 and the metal layer 612 thereon. Meanwhile, the two ends of the resistor 616a are electrically connected with the contact plugs 604c and 604c′ via the portions of the conductive layer 606 and the metal layer 612 therebetween. An insulating layer 624 is then formed on the resulting structure, possibly including a photoresist layer. Via/contact holes 626 are then formed in the insulating layer 624, respectively exposing a portion of the top electrode 620a, and a portion of the metal layer 612 over the through-substrate via 604a. A conductive layer 628 is then formed on the photoresist layer 624 and in the holes 626, possibly including a barrier layer and/or a seed layer. The examples of the materials of the barrier layer and the seed layer are as provided above.

Referring to FIG. 6F, another patterned photoresist layer 630 is then formed on the conductive layer 628, having therein trenches 632 that expose a plurality of portions of the conductive layer 628 including the portions of the conductive layer 628 in the holes 626. A metal material is then filled in the holes 626 and the trenches 632 to faun a via plug 634a in the hole 626 over the through-substrate via 604a, the contact plug 634b of the top electrode 620a in the hole 626 over the top electrode 620a, and the second metal layer (M2) 634c in the trenches 632.

Referring to FIG. 6G, the patterned photoresist layer 630 is then removed, and then the portions of the conductive layer 628 not covered by the via plug 634a, the contact plug 634b or the second metal layer (M2) 634c are removed.

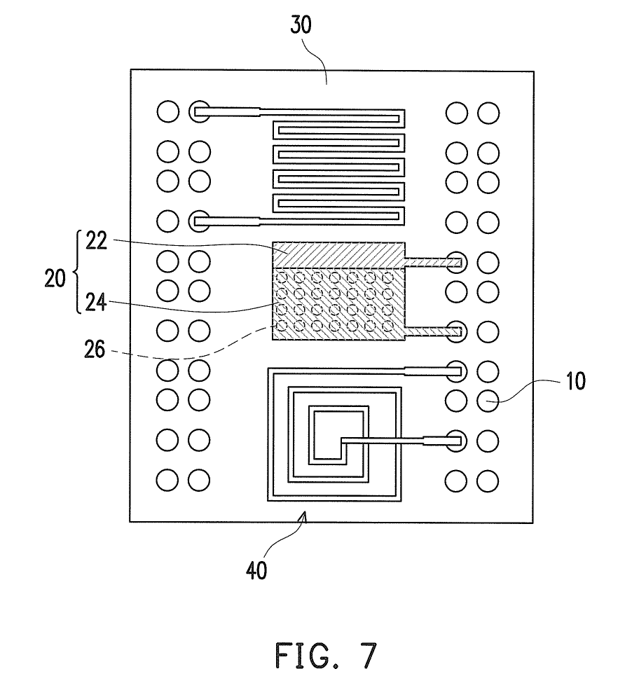

Though only the integration of capacitor and resistor structures in the interposer structure is described in the above embodiments, an inductor may also be integrated in the same interposer structure. FIG. 7 schematically illustrates, in a top view, such a chip-stack interposer structure integrated with various kinds of passive devices according to an embodiment of this invention.

Referring to FIG. 7, the interposer structure includes a plurality of through-substrate vias 10, and is integrated with a capacitor 20, a resistor 30 and an inductor 40, the pins of which are connected to different through-substrate vias 10. The capacitor 20 includes a bottom electrode 22 and a top electrode 24, which two may extend into trenches 26 in the interposer structure to increase the surface area and the capacitance, as mentioned above.

Accordingly, because the interposer structure or its fabrication method according to the above embodiments of this invention integrates one or more kinds of passive devices such as a capacitor and a resistor or its fabrication, inconvenience of connecting separately fabricated passive devices as seen in the prior art can be avoided.

Moreover, when the method of the above sixth embodiment is used to form a redistribution layer (RDL), no etching or CMP process is needed, so the cost of the RDL process can be remarkably lowered.

This invention has been disclosed above in the preferred embodiments, but is not limited to those. It is known to persons skilled in the art that some modifications and innovations may be made without departing from the spirit and scope of this invention. Hence, the scope of this invention should be defined by the following claims.

What is claimed is:

1. A chip-stack interposer structure including a passive device, comprising:
an interposing layer;
a capacitor, embedded in or disposed on the interposing layer, and comprising a first electrode, a second electrode, and a dielectric layer between the first electrode and the second electrode, wherein a portion of the first electrode does not overlap with the second electrode, and a portion of the second electrode does not overlap with the first electrode;
a first contact, connected with the first electrode; and
a second contact, connected with the second electrode,
wherein the first contact and the second contact are disposed at the same side of the interposing layer.

2. The chip-stack interposer structure of claim 1, further comprising a first insulating layer at a first side of the interposing layer, wherein the first contact and the second contact are disposed in the first insulating layer, penetrate the first electrode and the second electrode, respectively, and extend into the interposing layer.

3. The chip-stack interposer structure of claim 1, further comprising a first insulating layer at a first side of the interposing layer, wherein the first contact and the second contact are disposed in the first insulating layer and do not penetrate the first electrode and the second electrode.

4. The chip-stack interposer structure of claim 3, further comprising:
a through-substrate via in the interposing layer; and
a metal wiring, disposed in the first insulating layer and crossing over the through-substrate via.

5. The chip-stack interposer structure of claim 4, further comprising a second insulating layer between a surface of the first side of the interposing layer and the first insulating layer, wherein at least a portion of each of the first electrode and the second electrode is between the first insulating layer and the second insulating layer, and the metal wiring extends into the second insulating layer.

6. The chip-stack interposer structure of claim 4, wherein a dimension of the metal wiring is substantially the same as a dimension of the through-substrate via.

7. The chip-stack interposer structure of claim 4, wherein a dimension of the metal wiring is different from a dimension of the through-substrate via.

8. A chip-stack interposer structure including a passive device, comprising:
an interposing layer;
a capacitor, embedded in or disposed on the interposing layer, and comprising a first electrode, a second electrode, and a dielectric layer between the first electrode and the second electrode;
a first contact, connected with the first electrode; and
a second contact, connected with the second electrode,
wherein the first contact and the second contact are disposed at different sides of the interposing layer.

9. The chip-stack interposer structure of claim 8, further comprising an insulating layer at a first side of the interposing layer, wherein the first contact is disposed in the insulating layer, and the second contact is disposed in the interposing layer and extends toward a second side of the interposing layer.

10. A method for fabricating a chip-stack interposer structure including a passive device, comprising:
providing an interposing layer;
forming a capacitor embedded in or disposed on the interposing layer, wherein the capacitor comprises a first electrode, a second electrode, and a dielectric layer between the first electrode and the second electrode;
forming a first contact connected with the first electrode; and
forming a second contact connected with the second electrode.

11. The method of claim 10, wherein forming the capacitor comprises sequentially forming the first electrode, the dielectric layer and the second electrode, a portion of the first electrode does not overlap with the second electrode, a portion of the second electrode does not overlap with the first electrode, and the first contact and the second contact are disposed at the same side of the interposing layer.

12. The method of claim 11, further comprising:
forming an insulating layer at a first side of the interposing layer; and
forming a through-substrate via in the insulating layer and the interposing layer and simultaneously foaming the first contact and the second contact in the insulating layer, through the first electrode and the second electrode, respectively, and into the interposing layer.

13. The method of claim 11, further comprising:
forming an insulating layer at a first side of the interposing layer;
forming a through-substrate via in the insulating layer and the interposing layer; and
forming, in the insulating layer, the first contact and the second contact, which do not penetrate the first electrode and the second electrode.

14. The method of claim 11, further comprising:
forming a through-substrate via in the interposing layer;
forming a first insulating layer at a first side of the interposing layer; and
forming, in the first insulating layer, a metal wiring crossing over the through-substrate via, while the first contact and the second contact are formed.

15. The method of claim 14, further comprising: forming a second insulating layer on a surface of the first side of the interposing layer after the through-substrate via is formed but before the capacitor is formed, wherein at least a portion of each of the first electrode and the second electrode is between the first insulating layer and the second insulating layer, and the metal wiring extends into the second insulating layer.

16. The method of claim 10, wherein the first contact and the second contact are disposed at different sides of the interposing layer.

17. The method of claim 16, further comprising: forming an insulating layer at a first side of the interposing layer, wherein the first contact is formed in the insulating layer, and the second contact is formed in the interposing layer and extends toward a second side of the interposing layer.

18. The method of claim 17, further comprising:
forming a through-substrate via in the interposing layer while the second contact is formed; and
forming, in the insulating layer, a metal wiring crossing over the through-substrate via while the first contact is formed.

19. The method of claim 16, further comprising:
forming a through-substrate via in the interposing layer before the first electrode is formed;
forming a metal wiring crossing over the through-substrate via;
forming a first insulating layer over the metal wiring;
forming a second insulating layer after the second electrode is formed; and
forming the second contact in the second insulating layer.

20. The method of claim 19, further comprising:
forming a conductive layer over the interposing layer before the metal wiring is formed;
forming, on the conductive layer, a patterned photoresist layer, which has therein a trench exposing a portion of the conductive layer and crossing over the through-substrate via, wherein the metal wiring is formed in the trench later; and
removing the patterned photoresist layer after the metal wiring is formed in the trench.
